(19) United States
(12) Patent Application Publication
(10) Pub. No.: US 2023/0307254 A1
(43) Pub. Date: Sep. 28, 2023

(54) SUBSTRATE PROCESSING APPARATUS

(71) Applicant: SCREEN Holdings Co., Ltd., Kyoto (JP)

(72) Inventors: Yuta SEGAWA, Kyoto-shi (JP); Chiaki MORIYA, Kyoto-shi (JP)

(21) Appl. No.: 18/175,995

(22) Filed: Feb. 28, 2023

(30) Foreign Application Priority Data
Mar. 23, 2022 (JP) 2022-046970

(51) Int. Cl. H01L 21/67

(52) U.S. Cl. CPC H01L 21/67017

(57) ABSTRACT

A substrate processing apparatus includes a tower, a plurality of individual exhaust pipes, a collecting exhaust pipe, a switcher, an outside gas introducer, and a controller. The tower includes a plurality of processing parts aligned in a vertical direction. The switcher switches between connection and disconnection between each of the individual exhaust pipes and the collecting exhaust pipe. The outside gas introducer includes a flow passage introducing outside gas from outside to the collecting exhaust pipe. The controller controls the guide area of the outside gas introducer, based on individual guide areas corresponding to the plurality of processing parts and switching states of the switcher. The individual guide areas corresponding to the plurality of processing parts are set according to positions at which the plurality of processing parts are disposed.

### BACKGROUND OF THE INVENTION

### Field of the Invention

The present disclosure relates to a substrate processing apparatus.

### Description of the Background Art

Substrate processing apparatuses each processing a substrate have been conventionally proposed (for example, Japanese Patent Application Laid-Open No. 2020-47897 hereinafter referred to as Patent Document 1). In Patent Document 1, a substrate processing apparatus includes a plurality of processing parts stacked in a vertical direction. Each of the processing parts includes a processing chamber in which a processing fluid such as a processing liquid is supplied to a substrate. Consequently, a process corresponding to the processing fluid is performed on the substrate. Gases in the processing chambers are discharged outside through an exhaust system to be described later.

In Patent Document 1, the processing parts can sequentially supply an acid chemical liquid, an alkaline chemical liquid, and an organic solvent. When the processing parts supply the acid chemical liquid, the gas discharged from the processing chambers contains gas and mist generated from the acid chemical liquid. The fluid classification of the exhaust gas is acid gas. When the processing parts supply the alkaline chemical liquid, the gas discharged from the processing chambers contains gas and mist generated from the alkaline chemical liquid. The fluid classification of the exhaust gas is alkaline gas. When the processing parts supply the organic solvent, the gas discharged from the processing chambers contains gas and mist generated from the organic solvent. The fluid classification of the exhaust gas is organic gas.

The exhaust system causes these gases to be discharged to individual exhaust parts corresponding to the respective fluid classifications. In Patent Document 1, the exhaust system includes collecting pipes, a plurality of exhaust pipes, flow passage switchers, and outside gas introducers. The collecting pipes are disposed to correspond to the respective fluid classifications. Specifically, the collecting pipes consist of collecting pipes for acid gas, collecting pipes for alkaline gas, and collecting pipes for organic gas. These collecting pipes are disposed vertically higher than multilayer units including the plurality of processing parts stacked in the vertical direction.

The plurality of exhaust pipes are disposed to correspond to the plurality of processing parts. An upstream end of each of the exhaust pipes is connected to the processing chamber of the processing part, and a downstream end of the exhaust pipe is connected to one of the flow passage switchers. The flow passage switchers introduce the exhaust gases from the exhaust pipes to the collecting pipes corresponding to the respective fluid classifications. Specifically, each of the flow passage switchers introduces the exhaust gas from the processing part to one of the three collecting pipes according to the fluid classification. Since the processing parts sequentially switch and supply the processing liquids, the exhaust gas from each of the processing parts flows through the collecting pipe sequentially switched.

Since pressure variations in the collecting pipes are not favorable, the outside gas introducers cause an outside gas to flow through the collecting pipes through which the exhaust gas from any of the processing parts does not flow. This suppresses the pressure variations in the collecting pipes. For example, each of the flow passage switchers is connected to the downstream end of the outside gas introducer, and introduces the outside gas from the outside gas introducer to the collecting pipe that is not connected in communication with the exhaust pipes.

Since the plurality of processing parts are stacked in the vertical direction and the collecting pipes are disposed vertically higher than the multilayer units, the lengths of the exhaust pipes from the processing parts to the collecting pipes are different from one another. Thus, the exhaust gas from the processing part disposed at the highest position flows into the collecting pipe through the shortest exhaust pipe. Furthermore, the exhaust gas from the processing part disposed at the lowest position flows into the collecting pipe through the longest exhaust pipe. Thus, the amount of pressure variations of the collecting pipe according to a change in the fluid classification of the exhaust gas from the processing parts also depends on the position at which each of the processing parts is disposed. It is difficult to suppress such pressure variations with high accuracy.

### SUMMARY

The present disclosure is directed to a substrate processing apparatus.

The substrate processing apparatus according to one aspect of the disclosure includes: a first tower including a plurality of first processing parts which are aligned in a vertical direction and each of which processes a substrate; a plurality of first individual exhaust pipes through which respective gases discharged from the plurality of first processing parts flow; a first collecting exhaust pipe; a first switcher switching between connection and disconnection between each of the first individual exhaust pipes and the first collecting exhaust pipe; a first outside gas introducer including a flow passage introducing outside gas from outside to the first collecting exhaust pipe, the flow passage having a variable guide area; and a controller controlling the guide area of the first outside gas introducer, based on individual guide areas corresponding to the plurality of first processing parts and switching states of the first switcher, the individual guide areas corresponding to the plurality of first processing parts being set according to positions at which the plurality of first processing parts are disposed.

Since the individual guide areas corresponding to the plurality of first processing parts are set according to the positions at which the plurality of first processing parts are disposed, the pressure variations caused by differences in the positions can be reduced. In other words, the pressure variations in the first collecting exhaust pipe can be reduced with higher accuracy.

Preferably, the controller controls the guide area, based on a sum of the individual guide area(s) corresponding to first processing part(s) disconnected from the first collecting exhaust pipe from among the plurality of first processing parts, and the individual guide areas are set to larger values as the positions at which the plurality of first processing parts are disposed are higher.

Outside gas can compensate for the exhaust gases from the processing parts disconnected from the first collecting exhaust pipe. Thus, the pressure variations can be reduced with higher accuracy.

Preferably, the first outside gas introducer includes: a single guide pipe disposed in the first collecting exhaust pipe; and a movable part adjusting the guide area of the single guide pipe and controlled by the controller.

This provides for easy maintenance.

Preferably, the substrate processing apparatus further includes a storage in which individual area data indicating the individual guide areas corresponding the plurality of first processing parts is prestored, wherein the controller controls the movable part, based on the switching states and the individual area data.

This provides for easy maintenance.

Preferably, the first outside gas introducer includes: a plurality of guide pipes having the individual guide areas corresponding the plurality of first processing parts; and a plurality of on-off valves switching between opening and closing the plurality of guide pipes, wherein the controller controls the plurality of on-off valves based on the switching states.

Since the controller need not calculate the individual guide areas, the computation load of the controller can be reduced.

Preferably, the substrate processing apparatus includes: a second tower including a plurality of second processing parts which are aligned in the vertical direction and each of which processes a substrate, the second tower and the first tower being aligned in a horizontal direction; a plurality of second individual exhaust pipes through which respective gases discharged from the plurality of second processing parts flow; a second collecting exhaust pipe; a second switcher switching between connection and disconnection between each of the second individual exhaust pipes and the second collecting exhaust pipe; and a second outside gas introducer including a flow passage introducing outside gas from outside to the second collecting exhaust pipe, the flow passage having a variable guide area, wherein the controller controls the guide area of the second outside gas introducer, based on individual guide areas corresponding to the plurality of second processing parts and switching states of the second switcher, and the individual guide areas corresponding to the plurality of second processing parts being different from one another.

Although the exhaust gases from the first processing parts may flow into the first collecting exhaust pipe, no exhaust gas from the second processing parts flows thereto. Similarly, although the exhaust gases from the second processing parts may flow into the second collecting exhaust pipe, no exhaust gas from the first processing parts flows thereto. Consequently, the pressure variations caused by differences between the first and second towers can be reduced more reliably.

Thus, the object of this disclosure is to provide a technology for enabling reduction in the pressure variations in the exhaust pipes with higher accuracy.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view schematically illustrating an example structure of a substrate processing apparatus according to Embodiment 1;

FIG. 2 is a side view schematically illustrating the example structure of the substrate processing apparatus according to Embodiment 1;

FIG. 3 schematically illustrates one example connection relationship in an exhaust system according to Embodiment 1;

FIG. 4 is a functional block diagram schematically illustrating one example internal configuration of a controller;

FIG. 5 schematically illustrates one example when only a processing part at the highest position is connected in communication with a collecting exhaust pipe;

FIG. 6 schematically illustrates one example when only a processing part at the next highest position is connected in communication with the collecting exhaust pipe;

FIG. 7 schematically illustrates one example when only a processing part at the lowest position is connected in communication with the collecting exhaust pipe;

FIG. 8 is a plan view schematically illustrating an example structure of a substrate processing apparatus according to Embodiment 2;

FIG. 9 is a side view schematically illustrating the example structure of the substrate processing apparatus according to Embodiment 2;

FIG. 10 schematically illustrates one example connection relationship in an exhaust system according to Embodiment 2;

FIG. 11 is a perspective view schematically illustrating one example structure of an area adjustment part;

FIG. 12 schematically illustrates one example when only the processing part at the highest position is connected in communication with a collecting exhaust pipe;

FIG. 13 schematically illustrates one example when only the processing part at the next highest position is connected in communication with the collecting exhaust pipe; and

FIG. 14 schematically illustrates one example when only the processing part at the lowest position is connected in communication with the collecting exhaust pipe.

### DESCRIPTION OF THE PREFERRED EMBODIMENTS

Embodiments will be described below with reference to the attached drawings. The drawings are drawn in schematic form, and structures are appropriately omitted or simplified for convenience in description. The mutual relationships in size and position between the structures in the drawings are not necessarily accurate but may be changed when needed. Some of the drawings use an XYZ rectangular coordinate system to illustrate a position relationship between the structures. Here, a z axis is an axis along a vertical direction, and an x axis and a y axis are axes along a horizontal direction. One of the x axis directions may be referred to as a +x direction, and the other of the x axis directions may be referred to as a −x direction in the following description. The same applies to the y axis.

In the following description, the same reference numerals are assigned to the same constituent elements, and their names and functions are the same. Therefore, detailed description of such constituent elements may be omitted to avoid redundant description.

Even when the ordinal numbers such as “first” and “second” are used in following description, these terms are used for convenience to facilitate the understanding of the details of Embodiments. The order indicated by these ordinal numbers does not restrict the details of Embodiments.

Unless otherwise noted, the expressions indicating relative or absolute positional relationships (e.g., “in one direction”, “along one direction”, “parallel”, “orthogonal”, “central”, “concentric”, and “coaxial”) include those exactly indicating the positional relationships and those where an angle or a distance is relatively changed within tolerance or to the extent that similar functions can be obtained. Unless otherwise noted, the expressions indicating equality (e.g., “same”, “equal”, “uniform”, and “homogeneous”) include those indicating quantitatively exact equality and those in the presence of a difference within tolerance or to the extent that similar functions can be obtained. Unless otherwise noted, the expressions indicating shapes (e.g., “rectangular” or “cylindrical”) include those indicating geometrically exact shapes and those indicating, for example, roughness or a chamfer to the extent that similar advantages can be obtained. An expression “comprising”, “including”, “containing”, or “having” a certain constituent element is not an exclusive expression for excluding the presence of the other constituent elements. An expression “at least one of A, B, and C” involves “only A”, “only B”, “only C”, “arbitrary two of A, B, and C”, and “all of A, B, and C”.

### Embodiment 1

[Outline of Substrate Processing Apparatus]

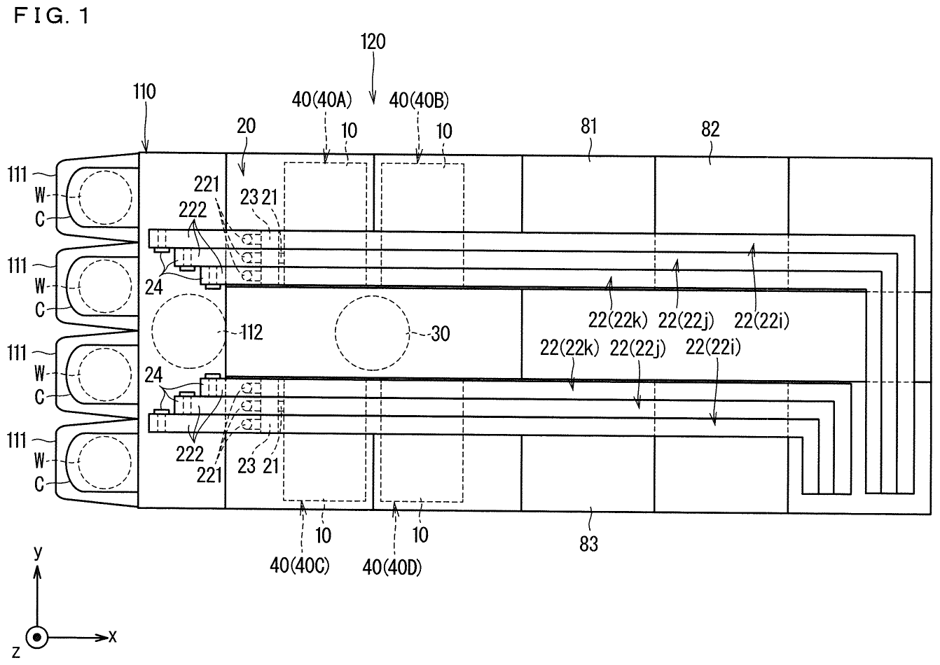

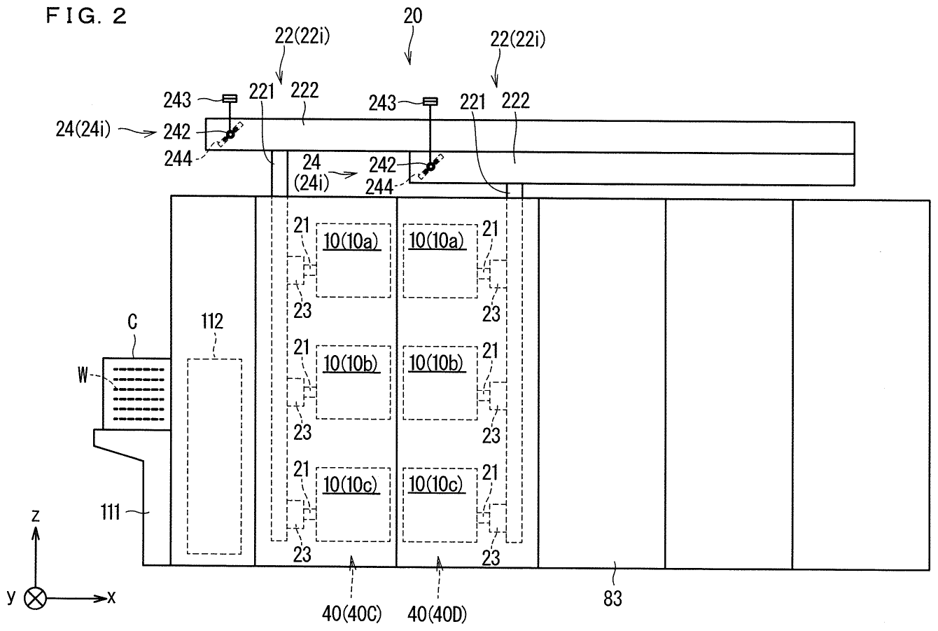

FIG. 1 is a plan view schematically illustrating an example structure of a substrate processing apparatus 100 according to Embodiment 1. FIG. 2 is a side view schematically illustrating the example structure of the substrate processing apparatus 100 according to Embodiment 1. The substrate processing apparatus 100 is a single wafer processing apparatus that processes a substrate W one by one in processing parts 10 to be described later.

The substrate W is, for example, a semiconductor substrate, and is disk-shaped. Various substrates are applicable as the substrate W. Besides the semiconductor substrate, the substrates include a photolithographic mask glass substrate, substrates for display such as a liquid crystal display glass substrate, a plasma display glass substrate, a field-emission display (FED) substrate, and an organic electro-luminescent (EL) substrate, an optical disk substrate, a magnetic disk substrate, a magneto-optical disk substrate, a ceramic substrate, and a solar cell substrate. The shape of the substrate is not limited to the disk shape but may be various shapes, for example, a rectangular plate shape.

In the example of FIGS. 1 and 2, the substrate processing apparatus 100 includes an indexer 110, an apparatus body 120, and a controller 90. The indexer 110 and the apparatus body 120 are aligned in the x axis direction. In the example of FIGS. 1 and 2, the apparatus body 120 is in the +x direction with respect to the indexer 110.

[Indexer]

The indexer 110 is an interface part for transporting the substrate W into the apparatus body 120 and the outside. Here, a substrate container (hereinafter referred to as a “carrier”) C that accommodates a plurality of substrates W is transported from the outside to the indexer 110.

The indexer 110 includes a plurality of load ports 111 and an indexer robot 112. Each of the load ports 111 holds the carrier C transported from the outside. In the example of FIG. 1, the plurality of load ports 111 are aligned in the y axis direction. The indexer robot 112 is a transport part that transports the substrate W between each of the carriers C and the apparatus body 120, and is in the +x direction with respect to the plurality of load ports 111. The indexer robot 112 sequentially unloads, from the carriers C, the substrates W to be processed, and transports the substrates W to the apparatus body 120. At the same time, the indexer robot 112 sequentially receives the substrates W processed by the apparatus body 120 from the apparatus body 120, and stores the substrates W in the carriers C. The carriers C accommodating the processed substrates W are transported out of the load ports 111.

[Apparatus Body]

The apparatus body 120 is a portion that processes the substrate W, and includes the plurality of processing parts 10, an exhaust system 20, and a center robot 30.

In the example of FIGS. 1 and 2, the plurality of processing parts 10 comprise a plurality of towers 40. Specifically, each of the towers 40 includes a plurality of the processing parts 10 aligned in the vertical direction. In the example of FIG. 1, four towers 40A to 40D are provided as the plurality of towers 40. Specifically, the four towers 40A to 40D are disposed on the top of a virtual rectangle in a plan view. Here, the towers 40A and 40B are aligned in the x axis direction, the towers 40C and 40D are aligned in the x axis direction, the towers 40A and 40C are aligned in the y axis direction, and the towers 40B and 40D are aligned in the y axis direction.

FIG. 2 illustrates example three processing parts 10a to 10c as the plurality of processing parts 10 included in each of the towers 40. The processing parts 10a to 10c are disposed in this order vertically from upward to downward. Specifically, the processing part 10a is disposed vertically at the highest position, and the processing part 10c is vertically disposed at the lowest position.

The center robot 30 is disposed at a position surrounded by the plurality of towers 40 in a plan view. The center robot 30 transports, into the processing parts 10, the substrates W to be processed and received from the indexer robot 112. Each of the processing parts 10 processes the substrates W. The center robot 30 transports the processed substrates W out of the processing parts 10, and passes the substrates W to the indexer robot 112.

In FIGS. 1 and 2, the contour of the processing chamber in each of the processing parts 10 is indicated by a broken-line rectangle. The processing chamber in each of the processing parts 10 includes various constituent elements including a substrate holding part and a nozzle part (not illustrated). The processing part 10 can supply, through the nozzle part, a plurality of kinds of processing fluids to the substrate W held by the substrate holding part. When the processing fluids are in liquid form, for example, the substrate holding part includes a rotation mechanism that rotates the substrate W, and the processing part 10 further includes a cup part surrounding the substrate holding part. The nozzle part supplies the processing fluid to the main surface of the substrate W being rotated. The processing fluid supplied to the substrate W flows through the main surface of the substrate W outward in a radial direction, is scattered from the periphery of the substrate W, and is received by the cup part. Since the processing fluid acts upon the substrate W, the process according to the processing fluid is performed on the substrate W. The processing fluid received by the cup part is appropriately retrieved.

The processing fluids used by the processing part 10 are classified into a plurality of fluid classifications. In Embodiment 1, the plurality of fluid classifications include an acid chemical liquid, an alkaline chemical liquid, and an organic solvent. The processing fluids may be in gaseous form.

Examples of the acid chemical liquid include chemical liquids made of dilute hydrofluoric acid (DHF), hydrochloric acid hydrogen peroxide mixture (SC2), buffered hydrofluoric acid (BHF), sulfuric acid, sulfuric acid hydrogen peroxide mixture (SPM), and nitrate fluoride (a mixed solution of hydrofluoric acid and nitric acid). Examples of the alkaline chemical liquid include chemical liquids made of ammonia hydrogen peroxide mixture (SC1), aqueous ammonia, ammonium fluoride solution, and tetramethylammonium hydroxide (TMAH). Examples of the organic solvent include solvents made of isopropyl alcohol (IPA), methanol, ethanol, hydrofluoroether (HFE), and acetone. The organic solvent may be a mixed solution, for example, a mixed solution of IPA and acetone, or a mixed solution of IPA and methanol.

In the example of FIG. 1, the substrate processing apparatus 100 further includes an acid chemical supply part 81, an alkaline chemical supply part 82, and an organic solvent supply part 83. The acid chemical supply part 81, the alkaline chemical supply part 82, and the organic solvent supply part 83 are in the +x direction with respect to the apparatus body 120. The acid chemical supply part 81 stores the acid chemical liquid, and supplies the acid chemical liquid to the nozzle part of each of the processing parts 10. The alkaline chemical supply part 82 stores the alkaline chemical liquid, and supplies the alkaline chemical liquid to the nozzle part of each of the processing parts 10. The organic solvent supply part 83 stores the organic solvent, and supplies the organic solvent to the nozzle part of each of the processing parts 10.

Furthermore, a fan filter unit (FFU) is disposed above each of the processing chambers, and produces airflow going downward inside the processing chamber. The gas in the processing chamber in each of the processing parts 10 is discharged out of the substrate processing apparatus 100 through the exhaust system 20. The gas to be discharged from the processing chamber in each of the processing parts 10 will be referred to as an exhaust gas.

[Exhaust System]

When the processing fluid is in liquid form, the exhaust gas discharged from each of the processing parts 10 contains evaporative compositions (gas) and mist from the processing fluid. While the nozzle part of the processing part 10 supplies an acid chemical liquid to the substrates W as a processing fluid, the exhaust gas contains gas and mist of the acid chemical liquid. Here, the exhaust gas is classified into one of the fluid classifications. The fluid classification of the exhaust gas is acid gas. While the nozzle part supplies an alkaline chemical liquid to the substrates W, the exhaust gas contains gas and mist of the alkaline chemical liquid. The fluid classification of the exhaust gas will be referred to as alkaline gas. While the nozzle part supplies an organic solvent to the substrates W, the exhaust gas contains gas and mist of the organic solvent. The fluid classification of the exhaust gas will be referred to as organic gas. Preferably, these exhaust gases are discharged separately according to the respective fluid classifications. The same applies when the processing fluid is in gaseous form.

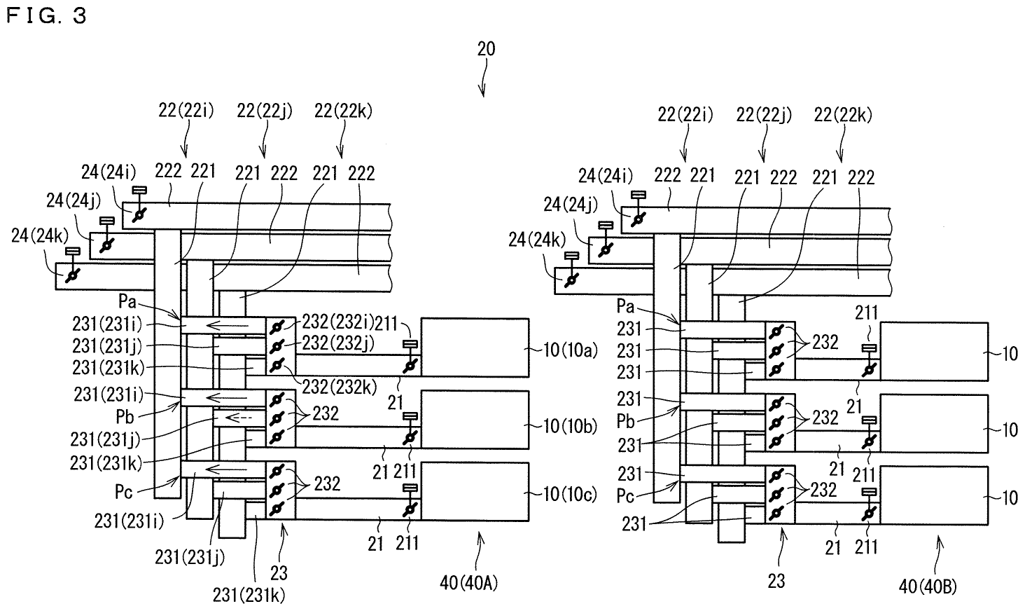

FIG. 3 schematically illustrates one example connection relationship in the exhaust system 20 according to Embodiment 1. Although FIG. 3 two-dimensionally illustrates the connection relationship between various pipes in the exhaust system 20, the actual pipes are disposed three-dimensionally.

The exhaust system 20 is a piping system that discharges the exhaust gas from each of the processing parts 10 outside of the substrate processing apparatus 100. The exhaust system 20 discharges the exhaust gas outside through an exhaust path corresponding to the fluid classification of the exhaust gas.

In the example of FIGS. 1 to 3, the exhaust system 20 includes individual exhaust pipes 21, collecting exhaust pipes 22, switchers 23, and outside gas introducers 24.

The individual exhaust pipes 21 are disposed to correspond to the processing parts 10. As a more specific example, the individual exhaust pipes 21 are disposed one-to-one with the processing parts 10. An upstream end of each of the individual exhaust pipes 21 is connected to a corresponding one of the processing parts 10. The exhaust gas from the processing part 10 flows into the upstream end of the individual exhaust pipe 21. Thus, the exhaust gas from the corresponding one of the processing parts 10 flows through the individual exhaust pipe 21.

As illustrated in FIG. 3, each of the individual exhaust pipes 21 may include a pressure adjustment part 211. The pressure adjustment part 211 includes, for example, a pressure sensor (not illustrated) that measures a pressure in the processing chamber of the processing part 10, and a flow rate adjuster (e.g., a dumper) that adjusts a flow rate of the exhaust gas flowing through the individual exhaust pipe 21. The controller 90 controls the flow rate adjuster based on the pressure sensor, so that the pressure in the processing chamber can be adjusted within a predetermined range.

Here, the exhaust gas from the processing part 10 flows through the individual exhaust pipe 21. Thus, the fluid classification of the exhaust gas is changed according to details of the process in the processing part 10 (i.e., the fluid classification of the processing fluid).

The switcher 23 introduces the exhaust gas from the individual exhaust pipe 21 to the collecting exhaust pipe 22 corresponding to the fluid classification. Specifically, the switcher 23 switches between connection and disconnection between the individual exhaust pipe 21 and each of the collecting exhaust pipes 22. An acid-gas collecting exhaust pipe 22, an alkaline-gas collecting exhaust pipe 22, and an organic-gas collecting exhaust pipe 22 will be hereinafter referred to as a collecting exhaust pipe 22i, a collecting exhaust pipe 22j, and a collecting exhaust pipe 22k, respectively. The switchers 23 are disposed one-to-one with the individual exhaust pipes 21, and are connected to the processing parts 10 through the individual exhaust pipes 21. Specifically, the switchers 23 are connected to downstream ends of the individual exhaust pipes 21.

Each of the switchers 23 includes a plurality of branch exhaust pipes 231 and a plurality of on-off valves 232 which are disposed to correspond the fluid classifications. Since there are three fluid classifications, the three branch exhaust pipes 231 are disposed for each of the processing parts 10. An acid-gas branch exhaust pipe 231, an alkaline-gas branch exhaust pipe 231, and an organic-gas branch exhaust pipe 231 will be hereinafter referred to as a branch exhaust pipe 231i, a branch exhaust pipe 231j, and a branch exhaust pipe 231k, respectively. Upstream ends of the branch exhaust pipes 231i to 231k are connected to the individual exhaust pipe 21, and downstream ends of the branch exhaust pipes 231i to 231k are connected to the collecting exhaust pipes 22i to 22k, respectively.

The on-off valve 232 is disposed at each of the branch exhaust pipes 231, and switches between opening and closing the branch exhaust pipe 231. The on-off valves 232 may be, example, butterfly valves or other types of valves. The on-off valves 232 disposed at the branch exhaust pipes 231i to 231k will be hereinafter referred to as on-off valves 232i to 232k, respectively.

The controller 90 controls, according to the fluid classification of the exhaust gas from the processing parts 10, the on-off valves 232 corresponding to the processing parts 10. Specifically, the controller 90 opens the on-off valves 232i and closes the on-off valves 232j and 232k when the fluid classification of the exhaust gas is acid gas. Accordingly, the exhaust gas flowing from the processing parts 10 to the switchers 23 through the individual exhaust pipes 21 flows into the acid-gas collecting exhaust pipe 22i through the branch exhaust pipes 231i. Furthermore, the controller 90 opens the on-off valves 232j and closes the on-off valves 232i and 232k when the fluid classification of the exhaust gas is alkaline gas. Accordingly, the exhaust gas from the processing parts 10 flows into the alkaline-gas collecting exhaust pipe 22j. Furthermore, the controller 90 opens the on-off valves 232k and closes the on-off valves 232i and 232j when the fluid classification of the exhaust gas is organic gas. Accordingly, the exhaust gas from the processing parts 10 flows into the organic-gas collecting exhaust pipe 22k.

As described above, the switchers 23 introduce the exhaust gas from the individual exhaust pipes 21 to the collecting exhaust pipe 22 corresponding to the fluid classification.

In the example of FIG. 2, the switcher 23 is disposed at a position adjacent to the corresponding processing part 10 in a horizontal direction. Thus, the switchers 23 corresponding to the processing parts 10a to 10c differ in height position. Specifically, the switcher 23 corresponding to the processing part 10a is disposed vertically at a position higher than the switchers 23 corresponding to the processing part 10b and 10c. The switcher 23 corresponding to the processing part 10c is disposed vertically at a position lower than the switchers 23 corresponding to the processing part 10a and 10b. The switcher 23 corresponding to the processing part 10b is disposed between the switchers 23 corresponding to the processing part 10a and 10c.

In the example of FIGS. 1 to 3, the collecting exhaust pipes 22 are disposed for each of the towers 40 and for the respective fluid classifications. Specifically, the collecting exhaust pipes 22i to 22k are disposed in the tower 40A, and other collecting exhaust pipes 22i to 22k different from those in the tower 40A are disposed in the tower 40B. The same applies to the towers 40C and 40D. Since the substrate processing apparatus 100 includes the four towers 40 and the three fluid classifications, it includes the twelve collecting exhaust pipes 22 in total.

In the example of FIG. 2, each of the collecting exhaust pipes 22 includes a vertical exhaust pipe 221 and a horizontal exhaust pipe 222. The vertical exhaust pipe 221 is disposed at a position adjacent to the corresponding tower 40 in a horizontal direction (e.g., the x axis direction), and extends along the z axis direction. The downstream ends of the branch exhaust pipes 231 corresponding to the processing parts 10a to 10c are connected to the vertical exhaust pipe 221 at different height positions. Specifically, the branch exhaust pipe 231 corresponding to the processing part 10a disposed at the highest position is connected to the vertical exhaust pipe 221 at a connection position vertically higher than the branch exhaust pipes 231 corresponding to the processing part 10b and 10c. For example, when attention is given to the branch exhaust pipes 231i, a connection position Pa between the branch exhaust pipe 231i corresponding to the processing part 10a and the vertical exhaust pipe 221 is higher than a connection position Pb between the branch exhaust pipe 231i corresponding to the processing part 10b and the vertical exhaust pipe 221, and the connection position Pb is higher than a connection position Pc between the branch exhaust pipe 231i corresponding to the processing part 10c and the vertical exhaust pipe 221.

In each of the collecting exhaust pipes 22, a lower end of the vertical exhaust pipe 221 is closed, and an upper end of the vertical exhaust pipe 221 is connected to the horizontal exhaust pipe 222. In the example of FIGS. 1 and 2, the horizontal exhaust pipes 222 are disposed vertically higher than the towers 40, and extend along the horizontal direction (mainly, the x axis direction). Specifically, the horizontal exhaust pipes 222 are disposed immediately above the towers 40 and extend along the x axis direction across the towers 40. The horizontal exhaust pipes 222 are bent in a −y direction at positions in the +x direction with respect to the alkaline chemical supply part 82 and extend. In the example of FIG. 1, the horizontal exhaust pipes 222 of the collecting exhaust pipes 22i to 22k corresponding to each of the towers 40 are aligned in the horizontal direction. Downstream ends of the horizontal exhaust pipes 222 are connected to factory pipes, and are further connected to exhaust facilities corresponding to the respective fluid classifications through the factory pipes. The vertical cross-sectional shape of the horizontal exhaust pipe 222 in the longitudinal direction is, for example, rectangular. The cross-sectional shape of the horizontal exhaust pipe 222 need not be rectangular but may be other shapes.

In the example of FIGS. 1 and 2, the horizontal exhaust pipe 222 of the collecting exhaust pipe 22i corresponding to the tower 40C and the horizontal exhaust pipe 222 of the collecting exhaust pipe 22i corresponding to the tower 40D are aligned in the z axis direction. Here, the horizontal exhaust pipe 222 of the collecting exhaust pipe 22i corresponding to the tower 40C and the horizontal exhaust pipe 222 of the collecting exhaust pipe 22i corresponding to the tower 40D extend in an overlapping manner in a plan view. The same applies to the collecting exhaust pipes 22j and 22k, and to the towers 40A and 40B.

The outside gas introducer 24 is a part for reducing the pressure variations in the collecting exhaust pipe 22 by introducing gas from the outside (hereinafter referred to as outside gas) to the collecting exhaust pipe 22. In the example of FIGS. 1 and 2, each of the collecting exhaust pipes 22 includes the outside gas introducer 24. In other words, the outside gas introducers 24 are disposed one-to-one with the collecting exhaust pipes 22. In the example of FIGS. 1 and 2, the outside gas introducer 24 corresponds to an end portion of the horizontal exhaust pipe 222 in the −x direction. The end of the horizontal exhaust pipe 222 in the −x direction is opened. Thus, outside gas can flow into the horizontal exhaust pipe 222 from this opening (an inlet). The end portion of the horizontal exhaust pipe 222 in the −x direction, which is disposed in the collecting exhaust pipe 22, can be understood as a single guide pipe that introduces outside gas. Specifically, the outside gas introducer 24 has a flow passage through which outside gas flows into the collecting exhaust pipe 22. The flow passage corresponds to a flow passage of the guide pipe (the end portion of the horizontal exhaust pipe 222).

An area of the flow passage of the guide pipe (hereinafter referred to as a guide area) is variable and can be controlled by the controller 90. For example, the outside gas introducer 24 includes a dumper 242, and a driving part 243 that adjusts a degree of opening of the dumper 242 (see FIG. 2). The dumper 242 includes a plate-shaped movable part 244 that is rotatable in the end portion of the horizontal exhaust pipe 222 in the −x direction (the guide pipe of the outside gas introducer 24). The movable part 244 is rotatable between a fully closed position at which the guide pipe of the outside gas introducer 24 is substantially fully closed and a fully open position at which the guide pipe of the outside gas introducer 24 is substantially fully opened. The rotation of the movable part 244 between the fully closed position and the fully open position can adjust the guide area. The degree of opening of the dumper 242 is represented by a rotation angle. Here, a degree of opening at which the outside gas introducer 24 is substantially fully closed is 0 degree, and a degree of opening at which the outside gas introducer 24 is substantially fully opened is 90 degrees.

The driving part 243 displaces (rotates herein) the movable part 244. The driving part 243 includes, for example, a motor. The driving part 243 is controlled by the controller 90, and adjusts a rotation position of the movable part 244. Specifically, the controller 90 controls the driving part 243 based on a switching state of the switcher 23 so that the rotation position of the movable part 244 and the guide area of the outside gas introducer 24 are adjusted. The controller 90 adjusts the guide area, so that the pressure variations in the collecting exhaust pipe 22 can be reduced with higher accuracy, which will be described later in detail.

Hereinafter, the outside gas introducers 24 included in the collecting exhaust pipes 22i to 22k will also be referred to as outside gas introducers 24i to 24k, respectively.

[Controller]

The controller 90 has centralized control over the substrate processing apparatus 100. Specifically, the controller 90 controls the indexer robot 112, the processing parts 10, the exhaust system 20 (specifically, the switchers 23 and the driving parts 243, etc.), and the center robot 30.

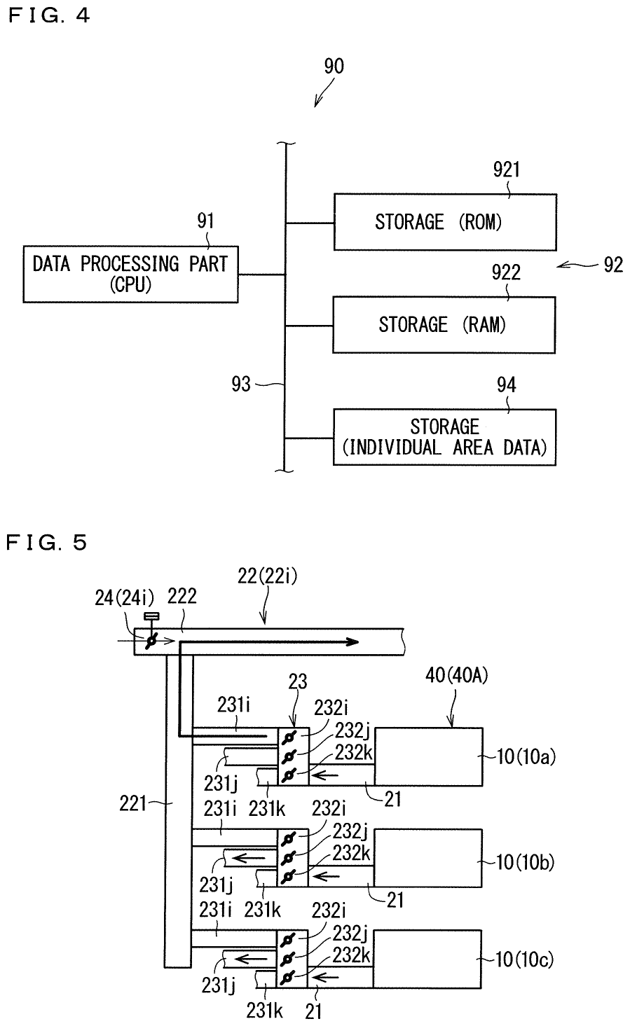

FIG. 4 is a functional block diagram schematically illustrating one example internal configuration of the controller 90. The controller 90 is an electronic circuit, and includes, for example, a data processing part 91 and a storage 92. In a specific example of FIG. 4, the data processing part 91 and the storage 92 are mutually connected through a bus 93. The data processing part 91 may be, for example, an arithmetic processing unit such as a central processing unit (CPU). The storage 92 may include a non-transitory storage (e.g., a read-only memory (ROM) or hard disk) 921 and a transitory storage (e.g., a random-access memory (RAM)) 922. The non-transitory storage 921 may store, for example, a program for defining processes to be executed by the controller 90. The data processing part 91 executes this program, so that the controller 90 can execute the processes defined in the program. Obviously, a hardware circuit such as a dedicated logic circuit may execute a part or all the processes to be executed by the controller 90.

[Exhaust Operations]

The controller 90 controls the switcher 23 based on the fluid classification of the exhaust gas from the processing part 10, and introduces the exhaust gas to the collecting exhaust pipe 22 corresponding to the fluid classification. Since the fluid classification of the exhaust gas of each of the processing parts 10 is sequentially changed, the controller 90 changes a switching state of the switcher 23 according to the change in the fluid classification, and appropriately introduces the exhaust gas from the processing part 10 to the collecting exhaust pipe 22. Thus, the flow rate of the exhaust gas flowing into each of the collecting exhaust pipes 22 is changed according to the change in the switching state of the switcher 23, which will be described below in detail.

For example, when the fluid classification of the exhaust gas from the processing parts 10a to 10c in the tower 40A is acid gas, the controller 90 opens the on-off valves 232i corresponding to the processing parts 10a to 10c. Accordingly, the exhaust gas from the processing parts 10a to 10c flows through the collecting exhaust pipe 22i. FIG. 3 schematically illustrates flows of these exhaust gases using solid-line arrows in the pipes as an example. Here, when the processing fluid supplied to the processing part 10b is changed, for example, from the acid chemical liquid to an alkaline chemical liquid, the controller 90 closes the on-off valve 232i corresponding to the processing part 10b, and opens the on-off valve 232j corresponding to the processing part 10b. This switches a destination into which the exhaust gas flows, from the collecting exhaust pipe 22i to the collecting exhaust pipe 22j. FIG. 3 schematically illustrates the flow of the exhaust gas after this switching using a dotted-line arrow in the pipe as an example. This switching reduces a flow rate of the exhaust gas flowing into the collecting exhaust pipe 22i by a flow rate corresponding to the processing part 10b, and increases a flow rate of the exhaust gas flowing into the collecting exhaust pipe 22j by the flow rate corresponding to the processing part 10b.

As such, a change in the number of the processing parts 10 connected in communication with each of the collecting exhaust pipes 22 changes a flow rate of the exhaust gas flowing into the collecting exhaust pipe 22.

Thus, the controller 90 controls the outside gas introducer 24 included in each of the collecting exhaust pipes 22 so that the guide area is adjusted. In the operation examples, the controller 90 increases the guide area of the outside gas introducer 24i and reduces the guide area of the outside gas introducer 24j by switching between opening and closing the on-off valves 232i and 232j corresponding to the processing part 10b. The increase in the guide area of the outside gas introducer 24i can compensate for the decrease in the exhaust gas from the processing part 10b using outside gas in the collecting exhaust pipe 22i, and reduce the pressure variations in the collecting exhaust pipe 22i. Furthermore, the decrease in the guide area of the collecting exhaust pipe 22j can reduce the outside gas flowing into the collecting exhaust pipe 22j. This can reduce the pressure variations in the collecting exhaust pipe 22j due to the flow of the exhaust gas from the processing part 10b into the collecting exhaust pipe 22j.

As such, the controller 90 controls the outside gas introducers 24 based on switching states of the plurality of switchers 23 so that the pressure variations in each of the collecting exhaust pipes 22 are reduced. The following description will focus attention on the collecting exhaust pipe 22i as a representative example.

The branch exhaust pipes 231i corresponding to the processing parts 10a to 10c are connected to the vertical exhaust pipe 221 of the collecting exhaust pipe 22i at different height positions. Thus, the lengths of the flow passages from the processing parts 10a to 10c to the horizontal exhaust pipe 222 of the collecting exhaust pipe 22i are different from one another. Specifically, the lengths of the flow passage are shorter in order of the processing parts 10a to 10c. More specifically, the length of the flow passage from the processing part 10a to the horizontal exhaust pipe 222 is the shortest, and the length of the flow passage from the processing part 10c to the horizontal exhaust pipe 222 is the longest.

Thus, even when only one of the processing parts 10 is connected in communication with the collecting exhaust pipe 22i, the pressure in the collecting exhaust pipe 22i may differ depending on which one of the processing parts 10a to 10c is connected in communication with the collecting exhaust pipe 22i.

The following will describe a switching state when only one of the processing parts 10 is connected in communication with the collecting exhaust pipe 22i. FIGS. 5 to 7 schematically illustrate examples when only one of the processing parts 10 is connected in communication with the collecting exhaust pipe 22i. In the example of FIG. 5, only the processing part 10a at the highest position is connected in communication with the collecting exhaust pipe 22i. Since the exhaust gas from the processing parts 10a flows through the collecting exhaust pipe 22i with the shortest flow passage, the exhaust gas easily flows through the collecting exhaust pipe 22i. Thus, FIG. 5 schematically illustrates the exhaust gas flowing from the processing part 10a into the collecting exhaust pipe 22i using a thick arrow.

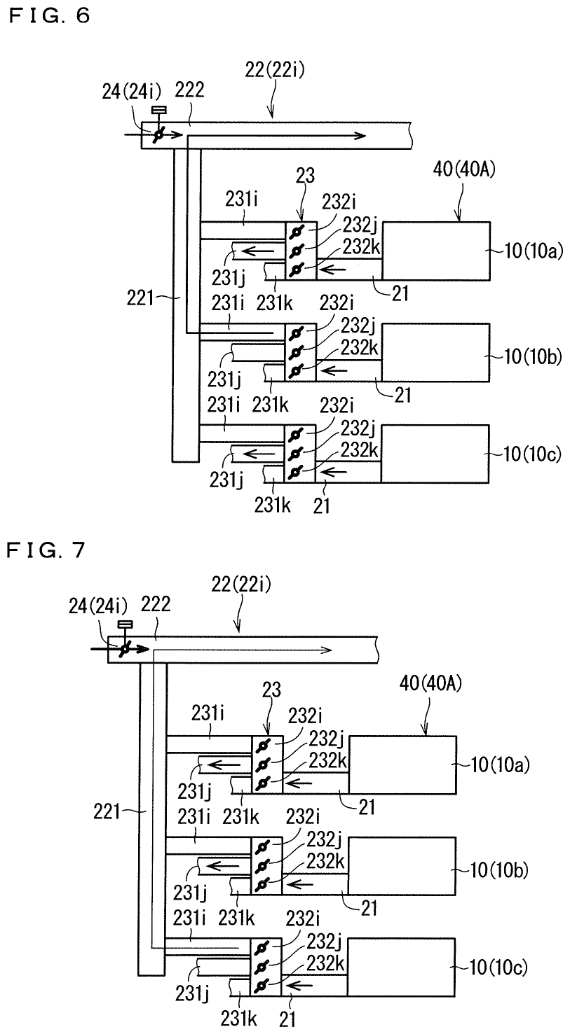

In the example of FIG. 6, only the processing part 10b at the next highest position is connected in communication with the collecting exhaust pipe 22i. Since the exhaust gas from the processing part 10b flows through the collecting exhaust pipe 22i with the flow passage longer than that corresponding to the processing part 10a, the exhaust gas resists flowing through the collecting exhaust pipe 22i more than the exhaust gas from the processing part 10a. Thus, FIG. 6 illustrates the exhaust gas flowing from the processing part 10b into the collecting exhaust pipe 22i using an arrow thinner than that indicating the exhaust gas from the processing part 10a in FIG. 5.

In the example of FIG. 7, only the processing part 10c at the lowest position is connected in communication with the collecting exhaust pipe 22i. Since the exhaust gas from the processing part 10c flows through the collecting exhaust pipe 22i with the longest flow passage, the exhaust gas resists flowing through the collecting exhaust pipe 22i the most. Thus, FIG. 7 illustrates the exhaust gas flowing from the processing part 10c into the collecting exhaust pipe 22i using an arrow thinner than those indicating the exhaust gases in FIGS. 5 and 6.

Since the flow rate of the gas flowing into the collecting exhaust pipe 22i is changed according to the processing part 10 connected in communication with the collecting exhaust pipe 22i, the pressure variations occur.

Here, even when the number of the processing parts 10 connected in communication with the collecting exhaust pipe 22i is consistent, the guide area of the outside gas introducer 24i is adjusted according to each of the processing parts 10 connected in communication with the collecting exhaust pipe 22i. Specifically, when only the processing part 10a is connected in communication with the collecting exhaust pipe 22i (FIG. 5), the guide area of the outside gas introducer 24i is set relatively smaller. When only the processing part 10b is connected in communication with the collecting exhaust pipe 22i (FIG. 6), the guide area of the outside gas introducer 24i is set larger than that when only the processing part 10a is connected in communication with the collecting exhaust pipe 22i. When only the processing part 10c is connected in communication with the collecting exhaust pipe 22i (FIG. 7), the guide area of the outside gas introducer 24i is set larger than that when only the processing part 10b is connected in communication with the collecting exhaust pipe 22i. Consequently, the pressure variations in the collecting exhaust pipe 22i can be reduced with higher accuracy.

Specifically, a guide area of the outside gas introducer 24i is set through the following operations. Here, an adjustment amount of the guide area (hereinafter referred to as an individual guide area) of the outside gas introducer 24 is preset for each of the processing parts 10a to 10c. Hereinafter, individual guide areas corresponding to the processing parts 10a to 10c will be referred to as individual guide areas A1 to A3, respectively. A specific method for setting each of the individual guide areas A1 to A3 will be described later in detail.

Assuming that “1” denotes an opened state of the on-off valve 232i and “0” denotes a closed state of the on-off valve 232i, there are eight switching states of the three switchers 23 on the collecting exhaust pipe 22i as described below. Specifically, when opened and closed states of the on-off valves 232i corresponding to the processing parts 10a to 10c are indicated in this order, the eight switching states are represented by (000), (001), (010), (100), (011), (101), (110), and (111).

The controller 90 sets a guide area A, based on a sum of individual guide area(s) corresponding to the processing part(s) 10 disconnected from the collecting exhaust pipe 22 from among the plurality of processing parts 10, which will be described in detail below. As a specific example, the controller 90 controls the guide area A of the outside gas introducer 24i included in the collecting exhaust pipe 22i, based on Equation (1) below.

A=Σ(αn·An) (n=1 to 3) (1)

Here, α1 to α3 correspond to the processing parts 10a to 10c, respectively. When the on-off valve 232i is opened, αn=0 holds. When the on-off valve 232i is closed, αn=1 holds. For example, when the on-off valve 232i corresponding to the processing parts 10a is opened, α1=0 holds. When the on-off valve 232i corresponding to the processing parts 10a is closed, α1=1 holds.

Table 1 below is a table indicating one example of the guide area A based on Equation (1).

TABLE 1

| SWITCHING | AREA OF | SWITCHING | AREA OF |
|---|---|---|---|
| STATE | INLET | STATE | INLET |
| (111) | 0 | (100) | A2 + A3 |
| (110) | A3 | (010) | A1 + A3 |
| (101) | A2 | (001) | A1 + A2 |
| (011) | A1 | (000) | A1 + A2 + A3 |

As understood from Table 1, individual guide areas An corresponding to the processing parts 10 disconnected from the collecting exhaust pipe 22i are used in calculating the guide area A. For example, the processing parts 10b and 10c are disconnected from the collecting exhaust pipe 22i in the switching state (100). The sum of the individual guide areas A2 and A3 corresponding to the processing parts 10b and 10c is the guide area A.

The individual guide areas A1 to A3 are set to different values, and are specifically set to values corresponding to the positions at which the processing parts 10 are disposed. More specifically, the individual guide areas A1 to A3 are set to larger values as the positions at which the processing parts 10 are disposed are higher. Thus, the individual guide area A1 is set to a value larger than those of the individual guide areas A2 and A3. The individual guide area A2 is set to a value between those of the individual guide areas A1 and A3. The individual guide area A3 is set to a value smaller than those of the individual guide areas A1 and A2. Thus, the guide area A is larger as its location in Table 1 is in a lower tier and in a right column. The individual guide areas A1 to A3 may be set to, for example, values corresponding to flow rates of the gases discharged from the processing parts 10a to 10c, respectively.

Individual area data indicating the individual guide areas A1 to A3 corresponding to the processing parts 10 is prestored in, for example, a storage 94. The storage 94 is a non-transitory storage, for example, a storage such as a memory and hard disk. In the example of FIG. 4, the storage 94 is also connected to the bus 93. The controller 90 reads the individual area data from the storage 94, and understands the individual guide areas A1 to A3 corresponding to the processing parts 10, based on the individual area data.

The individual guide area An can be expressed by a product of a constant K and a weighting factor ωn. Here, the weighting factor ωn should be set according to the position at which the processing part 10 is disposed.

The controller 90 obtains the guide area A using Equation (1) based on the switching state of the switcher 23, and controls the driving part 243 of the outside gas introducer 24i so that the guide area of the outside gas introducer 24i is equal to the obtained guide area A.

The following will describe representative control over the outside gas introducer 24 based on Equation (1), when only one of the processing parts 10 is connected in communication with the collecting exhaust pipe 22i. FIG. 5 illustrates the switching state (100), FIG. 6 illustrates the switching state (010), and FIG. 7 illustrates the switching state (001).

According to Equation (1), the guide area A (100) in the switching state (100) where only the processing part 10a is connected in communication with the collecting exhaust pipe 22i is controlled as (A2+A3), the guide area A (010) in the switching state (010) where only the processing part 10b is connected in communication with the collecting exhaust pipe 22i is controlled as (A1+A3), and the guide area A (001) in the switching state (001) where only the processing part 10c is connected in communication with the collecting exhaust pipe 22i is controlled as (A1+A2).

Since the individual guide areas A1 to A3 are smaller as the last digits of the reference numerals are larger, the guide area A (100) is smaller than the guide area A (010), and the guide area A (010) is smaller than the guide area A (001). In the example of FIG. 5, a thin arrow indicates outside gas flowing into the collecting exhaust pipe 22i through the outside gas introducer 24i. In the example of FIG. 6, an arrow thicker than that in FIG. 5 indicates outside gas flowing into the collecting exhaust pipe 22i through the outside gas introducer 24i. In the example of FIG. 7, an arrow thicker than that in FIG. 6 indicates outside gas flowing into the collecting exhaust pipe 22i through the outside gas introducer 24i.

As described above, even when the number of the processing parts 10 connected in communication with the collecting exhaust pipe 22i is consistent, the guide area A is smaller as the positions at which the processing parts 10 connected in communication with the collecting exhaust pipe 22i are disposed are higher. This enables outside gas to flow into the collecting exhaust pipe 22i at an appropriate flow rate corresponding to the fluidity of the exhaust gas flowing through the collecting exhaust pipe 22i. Thus, the pressure variations in the collecting exhaust pipe 22i can be reduced with higher accuracy. The same applies to the collecting exhaust pipes 22j and 22k.

In the examples above, the individual guide areas A1 to A3 are set according to the flow rates of the exhaust gases discharged from the processing parts 10a to 10c, respectively. This can add outside gas equivalent to the exhaust gas from the processing parts 10 disconnected from the collecting exhaust pipe 22i, to the collecting exhaust pipe 22i through the outside gas introducer 24i. For example, in the switching state (100) where only the processing part 10a is connected in communication with the collecting exhaust pipe 22i and the processing parts 10b and 10c are disconnected from the collecting exhaust pipe 22i, the guide area A is adjusted as (A2+A3). This enables the outside gas equivalent to the exhaust gas from the processing parts 10b and 10c to flow into the collecting exhaust pipe 22i through the outside gas introducer 24i. Accordingly, the gas equivalent in amount to the exhaust gas from the processing parts 10a to 10c flows through the collecting exhaust pipe 22i. The same applies to the other switching states. Thus, the pressure variations in the collecting exhaust pipe 22i caused by a change in the switching state can be ideally resolved.

In the examples above, the outside gas introducer 24 includes the single guide pipe disposed in the collecting exhaust pipe 22 (the end portion of the horizontal exhaust pipe 222 in the −x direction), and the movable part 244 for adjusting the guide area. Consequently, the number of the movable parts 244 for adjusting the guide areas can be reduced more than that when the collecting exhaust pipe 22 includes a plurality of guide pipes. Thus, the manufacturing cost can be reduced. Furthermore, the substrate processing apparatus 100 is easily maintained.

In the examples above, the individual area data indicating the individual guide areas corresponding to the processing parts 10 is prestored in the storage 94. The controller 90 controls the rotation position of the movable part 244 based on the individual area data and a switching state of the switcher 23.

The examples described on the collecting exhaust pipe 22i apply to the collecting exhaust pipes 22j and 22k. Here, the individual guide areas A1 to A3 may be set according to the respective fluid classifications. Specifically, the individual guide areas A1 to be used for calculating the guide areas corresponding to the outside gas introducers 24i, 24j, and 24k may be independently set in each of the towers 40. The same applies to the individual guide areas A2 and A3. This can set the individual guide areas A1 to A3 appropriate for the respective fluid classifications.

In the example of FIGS. 1 and 2, the collecting exhaust pipe 22i is disposed for each of the towers 40. Specifically, the substrate processing apparatus 100 includes the collecting exhaust pipe 22i corresponding to the tower 40A, the collecting exhaust pipe 22i corresponding to the tower 40B, the collecting exhaust pipe 22i corresponding to the tower 40C, and the collecting exhaust pipe 22i corresponding to the tower 40D. This can inhibit the exhaust gas from the different tower 40 from entering the collecting exhaust pipes 22i. Since the individual guide areas A1 to A3 can be independently set in each of the towers 40, the individual guide areas A1 to A3 appropriate for the respective towers 40 can be set. Consequently, the pressure variations in the collecting exhaust pipes 22i which are caused by differences in the towers 40 can be reduced with higher accuracy. The same applies to the collecting exhaust pipes 22j and 22k.

Here, the terms in SUMMARY are associated with the terms in DESCRIPTION OF THE PREFERRED EMBODIMENTS. One of the towers 40A to 40D corresponds to a first tower, and another one thereof corresponds to a second tower. The processing part 10 belonging to one of the towers 40A to 40D (i.e., the first tower) corresponds to a first processing part. The processing part 10 belonging to another one of the towers 40A to 40D (i.e., the second tower) corresponds to a second processing part. The individual exhaust pipe 21 connected to the first processing part corresponds to a first individual exhaust pipe. The individual exhaust pipe 21 connected to the second processing part corresponds to a second individual exhaust pipe. The switcher 23 connected to the first individual exhaust pipe corresponds to a first switcher, and the switcher 23 connected to the second individual exhaust pipe corresponds to a second switcher. Each of the collecting exhaust pipes 22i to 22k connected to the first switcher corresponds to a first collecting exhaust pipe. Each of the collecting exhaust pipes 22i to 22k connected to the second switcher corresponds to a second collecting exhaust pipe. Each of the outside gas introducers 24i to 24k disposed in the first collecting exhaust pipes corresponds to a first outside gas introducer. Each of the outside gas introducers 24i to 24k disposed in the second collecting exhaust pipes corresponds to a second outside gas introducer.

### Embodiment 2

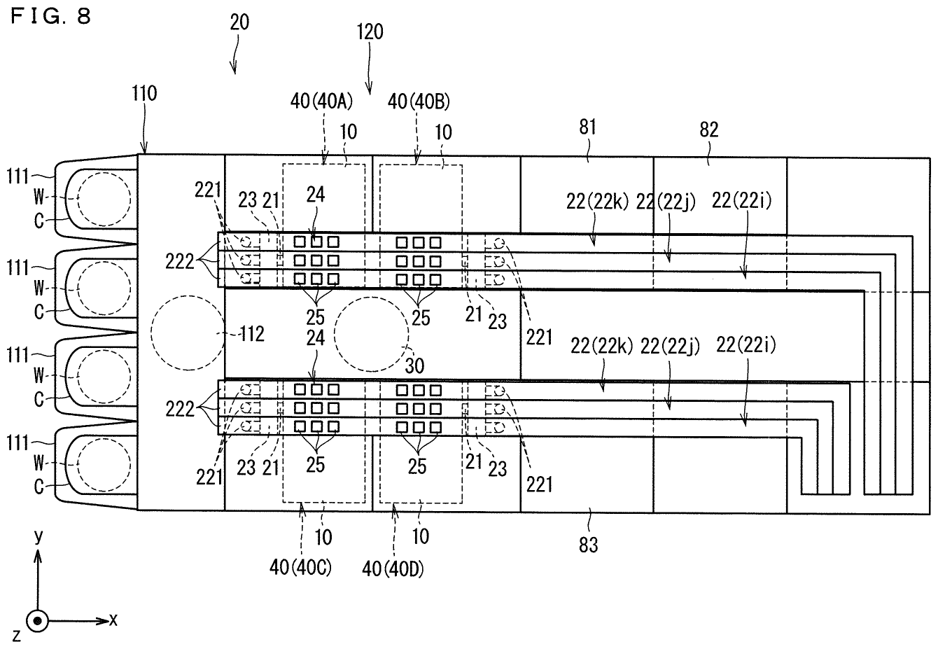

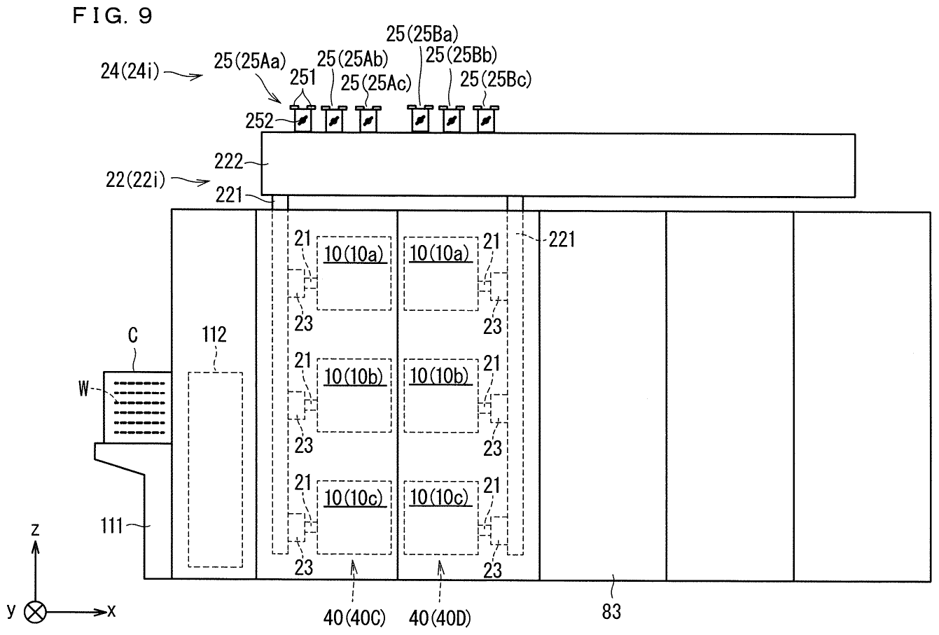

FIG. 8 is a plan view schematically illustrating an example structure of the substrate processing apparatus 100 according to Embodiment 2. FIG. 9 is a side view schematically illustrating the example structure of the substrate processing apparatus 100 according to Embodiment 2. In the example of FIG. 8, one collecting exhaust pipe 22i is disposed for two of the towers 40 adjacent in the x axis direction. Specifically, the substrate processing apparatus 100 includes the collecting exhaust pipe 22i common to the towers 40A and 40B, and the collecting exhaust pipe 22i common to the towers 40C and 40D. The same applies to the collecting exhaust pipes 22j and 22k.

As described in Embodiment 1, the horizontal exhaust pipe 222 of each of the collecting exhaust pipes 22 is disposed vertically higher than the towers 40. The vertical cross-sectional shape of the horizontal exhaust pipe 222 in the longitudinal direction is, for example, rectangular. In the example of FIGS. 8 and 9, the width of the horizontal exhaust pipe 222 in the vertical direction in the cross section is greater than the width thereof in the horizontal direction. This can reduce a total width (a horizontal width) of the three horizontal exhaust pipes 222 arranged adjacent to each other in the horizontal direction. This inhibits the airflow from the fan filter units immediately above the processing parts 10, from being obstructed by the horizontal exhaust pipes 222. The ends of the horizontal exhaust pipes 222 in the −x direction are not opened but closed.

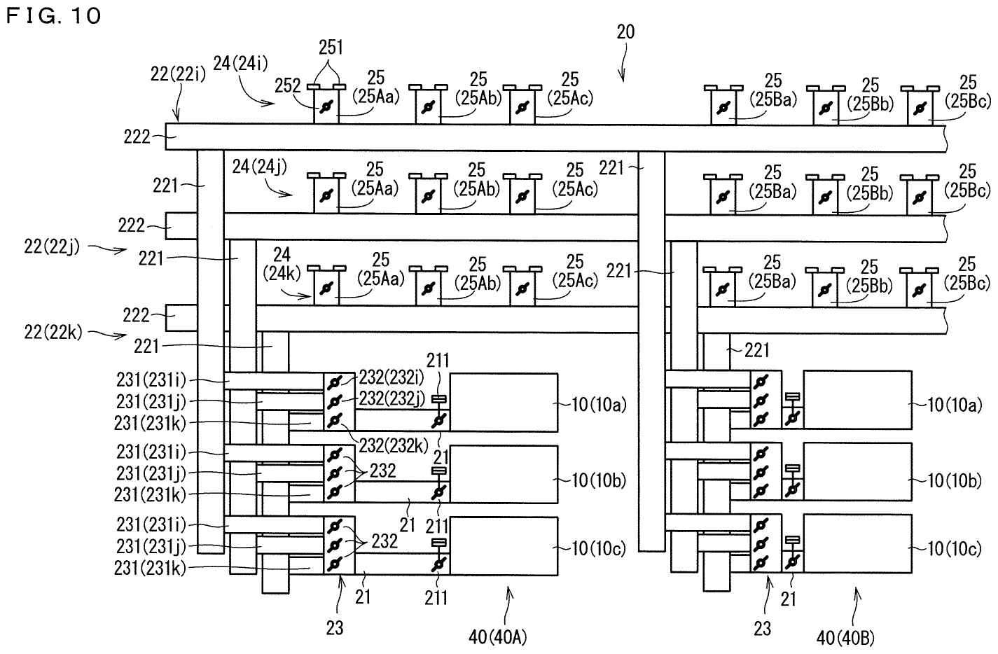

FIG. 10 schematically illustrates one example connection relationship in the exhaust system 20 according to Embodiment 2. Although FIG. 10 two-dimensionally illustrates the connection relationship between various pipes in the exhaust system 20, the actual pipes are disposed three-dimensionally.

In Embodiment 2, the outside gas introducer 24 included in each of the collecting exhaust pipes 22 includes a plurality of guide pipes 25 corresponding one-to-one to the plurality of processing parts 10. Since the six processing parts 10 belonging to the two towers 40 in total correspond to each of the collecting exhaust pipes 22, six of the guide pipes 25 are disposed for the collecting exhaust pipe 22. In the example of FIGS. 8 to 10, the six guide pipes 25 are aligned on each of the collecting exhaust pipes 22 in the longitudinal direction (the x axis direction herein) of the horizontal exhaust pipe 222.

In the example of FIG. 9, the downstream ends of the guide pipes 25 are connected to the upper surface of the horizontal exhaust pipe 222 of the collecting exhaust pipe 22. The guide pipes 25 extend vertically upward from the downstream ends, and have upper ends that are opened vertically upward. Outside gas flows into each of the guide pipes 25 from the upstream opening thereof, and then flows into the horizontal exhaust pipe 222 through the guide pipes 25. The cross-sectional shape of each of the guide pipes 25 vertical in a direction in which the outside gas flows may be rectangular, or, for example, circular.

The outside gas introducer 24 includes an area adjustment part 251 and an on-off valve 252 in each of the guide pipes 25. The on-off valve 252 is disposed in the guide pipe 25, and switches between opening and closing the guide pipe 25. The on-off valves 252 may be, for example, butterfly valves or other types of valves.

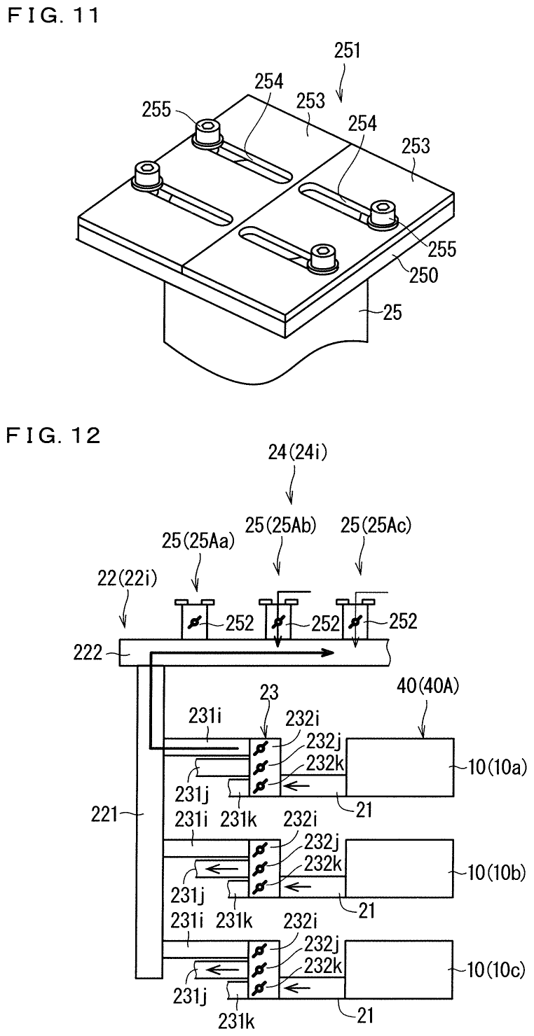

The area adjustment part 251 is a part that adjusts a flow passage area (an individual guide area) of the guide pipe 25. FIG. 11 is a perspective view schematically illustrating one example structure of the area adjustment part 251. In the example of FIG. 11, the area adjustment part 251 includes a pair of plate parts 253. The plate parts 253 are attached to the upper-end opening of the guide pipe 25. Specifically, a mounting plate 250 is disposed on the upper end of the guide pipe 25, and the pair of plate parts 253 is attached to the mounting plate 250. The pair of plate parts 253 is aligned in an alignment direction parallel to the upper-end opening of the guide pipe 25.

A plurality of long holes 254 are formed in the alignment direction in each of the plate parts 253. The long holes 254 penetrate each of the plate parts 253 into a thickness direction. The plate parts 253 are attached to the mounting plate 250 with screws 255 penetrating the long holes 254 and being threaded into threaded holes on the mounting plate 250. Such a structure can change positions at which the plate parts 253 are attached to the mounting plate 250 within ranges of the long holes 254 in the longitudinal direction (alignment direction). This can adjust spacings between the pairs of plate parts 253, and adjust areas of the upstream openings (individual guide areas) of the guide pipes 25.

The individual guide area of each of the guide pipes 25 is set to a larger value as the corresponding processing part 10 is at a higher position. Here, the collecting exhaust pipe 22i corresponding to the towers 40A and 40B will be described. The collecting exhaust pipe 22i includes the total six guide pipes 25 corresponding to the three processing parts 10a to 10c of the tower 40A and the three processing parts 10a to 10c of the tower 40B. The guide pipes 25 are distinguished from one another, each using the last alphabet of the reference numeral of the tower 40 and the last alphabet of the reference numeral of the processing part 10. For example, a guide pipe 25Aa is the guide pipe 25 corresponding to the processing part 10a of the tower 40A.

An individual guide area of the guide pipe 25Aa is set to a value corresponding to the flow rate of the exhaust gas discharged from the processing part 10a in the tower 40A. An individual guide area of the guide pipe 25Ab is set to a value corresponding to the flow rate of the exhaust gas discharged from the processing part 10b in the tower 40A. An individual guide area of the guide pipe 25Ac is set to a value corresponding to the flow rate of the exhaust gas discharged from the processing part 10c in the tower 40A. Similarly, an individual guide area of the guide pipe 25Ba is set to a value corresponding to the flow rate of the exhaust gas discharged from the processing part 10a in the tower 40B. An individual guide area of the guide pipe 25Bb is set to a value corresponding to the flow rate of the exhaust gas discharged from the processing part 10b in the tower 40B. An individual guide area of the guide pipe 25Bc is set to a value corresponding to the flow rate of the exhaust gas discharged from the processing part 10c in the tower 40B.

Here, the individual guide area of the guide pipe 25Aa is set larger than that of the guide pipe 25Ab, and the individual guide area of the guide pipe 25Ab is set larger than that of the guide pipe 25Ac. This is because the exhaust gas more easily flows and the flow rate is higher as the position at which the processing part 10 is disposed is higher. Similarly, the individual guide area of the guide pipe 25Ba is set larger than that of the guide pipe 25Bb, and the individual guide area of the guide pipe 25Bb is set larger than that of the guide pipe 25Bc. The user adjusts the area adjustment part 251 corresponding to each of the guide pipes 25, so that the individual guide area is set.

Outside gas flows into the collecting exhaust pipe 22i through the guide pipes 25 whose on-off valves 252 are open, from among the plurality of guide pipes 25 of the outside gas introducer 24i. Thus, the guide area A of the outside gas introducer 24i can be defined as a sum of the individual guide area(s) of the guide pipe(s) 25 whose on-off valves 252 are open. Specifically, the guide area A is adjusted by the on-off valves 252. For example, when all the six on-off valves 252 are open, the guide area A is equal to a sum of the individual guide areas of the six guide pipes 25. When the on-off valve 252 of only the guide pipe 25Aa is open, the guide area A is the individual guide area of the guide pipe 25Aa.

The controller 90 controls the guide area of the outside gas introducer 24i so that outside gas corresponding to the exhaust gases from the processing parts 10 disconnected from the collecting exhaust pipe 22i flows into the collecting exhaust pipe 22i. In other words, the controller 90 controls the plurality of on-off valves 252 based on the switching states of the plurality of switchers 23. Specifically, the controller 90 opens the on-off valve(s) 252 of the guide pipe(s) 25 corresponding to the processing part(s) 10 disconnected from the collecting exhaust pipe 22i, and closes the on-off valve(s) 252 of the guide pipe(s) 25 corresponding to the processing part(s) 10 connected in communication with the collecting exhaust pipe 22i. Furthermore, opened and closed states of the on-off valve 232 and the on-off valve 252 corresponding to the same processing part 10 are opposite to one another in each of the collecting exhaust pipes 22. For example, the controller 90 controls opened and closed states of the on-off valve 252 of the guide pipe 25Aa corresponding to the processing part 10a opposite to those of the on-off valve 232i corresponding to the processing part 10a in the tower 40A.

The following will describe representative exhaust operations in the tower 40A when only one of the processing parts 10 is connected in communication with the collecting exhaust pipe 22i. In other words, the tower 40B will be disregarded in the following description for the sake of simplicity. FIGS. 12 to 14 schematically illustrate examples when only one of the processing parts 10 is connected in communication with the collecting exhaust pipe 22i. In the example of FIG. 12, only the processing part 10a at the highest position is connected in communication with the collecting exhaust pipe 22i. Specifically, the on-off valve 232i corresponding to the processing part 10a is opened, and the on-off valves 232i corresponding to the processing parts 10b and 10c are closed in the example of FIG. 12. Since the exhaust gas from the processing part 10a flows through the collecting exhaust pipe 22i with the shortest flow passage, the exhaust gas easily flows through the collecting exhaust pipe 22i.

Here, the controller 90 controls the on-off valves 252 of the guide pipes 25 opposite to the opened and closed states of the on-off valves 232i. Specifically, the controller 90 closes the on-off valve 252 of the guide pipes 25Aa, and opens the on-off valves 252 of the guide pipes 25Ab and 25Ac. More specifically, the controller 90 controls the guide area A of the outside gas introducer 24i as a sum of the individual guide areas of the guide pipes 25Ab and 25Ac. This allows outside gas to flow into the collecting exhaust pipe 22i through the guide pipes 25Ab and 25Ac. Since the individual guide areas of the guide pipes 25Ab and 25Ac are set to values corresponding to the flow rates of the exhaust gases discharged from the processing parts 10b and 10c, outside gas can compensate for the exhaust gases discharged from the processing parts 10b and 10c in the collecting exhaust pipe 22i.

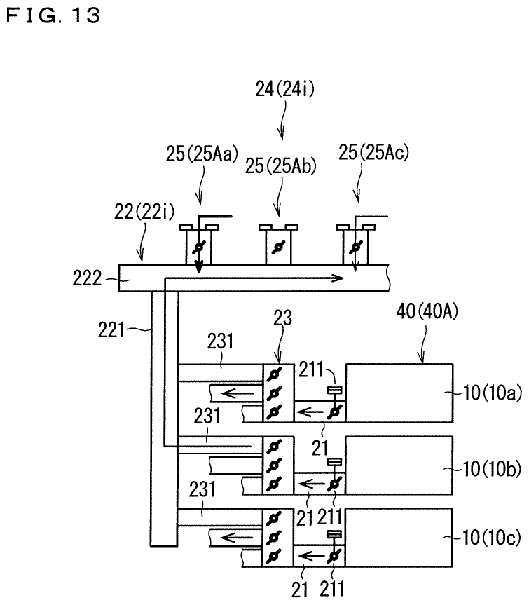

In the example of FIG. 13, only the processing part 10b at the next highest position is connected in communication with the collecting exhaust pipe 22i. Specifically, the on-off valve 232i corresponding to the processing part 10b is opened, and the on-off valves 232i corresponding to the processing parts 10a and 10c are closed in the example of FIG. 13. Since the exhaust gas from the processing part 10b flows through the collecting exhaust pipe 22i with the flow passage longer than that corresponding to the processing part 10a, the exhaust gas resists flowing through the collecting exhaust pipe 22i more than the exhaust gas from the processing part 10a.

Here, the controller 90 controls the on-off valves 252 of the guide pipes 25 opposite to the opened and closed states of the on-off valves 232i. Specifically, the controller 90 closes the on-off valve 252 of the guide pipe 25Ab, and opens the on-off valves 252 of the guide pipes 25Aa and 25Ac. More specifically, the controller 90 controls the guide area A of the outside gas introducer 24i as a sum of the individual guide areas of the guide pipes 25Aa and 25Ac. This allows outside gas to flow into the collecting exhaust pipe 22i through the guide pipes 25Aa and 25Ac. Since the individual guide areas of the guide pipes 25Aa and 25Ac are set to values corresponding to the flow rates of the exhaust gases discharged from the processing parts 10a and 10c, outside gas can compensate for the exhaust gases discharged from the processing parts 10a and 10c in the collecting exhaust pipe 22i.

Since the individual guide area of the guide pipe 25Aa is set larger than that of the guide pipe 25Ab, the flow rate of outside gas flowing into the collecting exhaust pipe 22i in FIG. 13 is higher that of outside gas flowing into the collecting exhaust pipe 22i in FIG. 12.

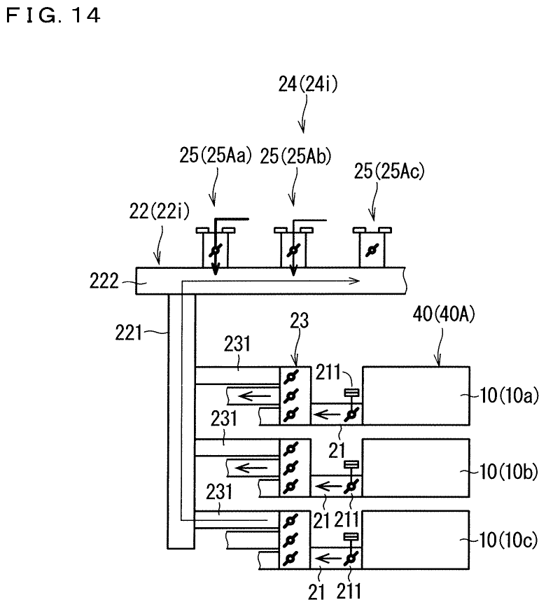

In the example of FIG. 14, only the processing part 10c at the lowest position is connected in communication with the collecting exhaust pipe 22i. Specifically, the on-off valve 232i corresponding to the processing part 10c is opened, and the on-off valves 232i corresponding to the processing parts 10a and 10b are closed in the example of FIG. 14. Since the exhaust gas from the processing parts 10c flows through the collecting exhaust pipe 22i with the longest flow passage, the exhaust gas resists flowing through the collecting exhaust pipe 22i the most.

Here, the controller 90 controls the on-off valves 252 of the guide pipes 25 opposite to the opened and closed states of the on-off valves 232i. Specifically, the controller 90 closes the on-off valve 252 of the guide pipe 25Ac, and opens the on-off valves 252 of the guide pipes 25Aa and 25Ab. More specifically, the controller 90 controls the guide area A of the outside gas introducer 24i as a sum of the individual guide areas of the guide pipes 25Aa and 25Ab. This allows outside gas to flow into the collecting exhaust pipe 22i through the guide pipes 25Aa and 25Ab. Since the individual guide areas of the guide pipes 25Aa and 25Ab are set to values corresponding to the flow rates of the exhaust gases discharged from the processing parts 10a and 10b, outside gas can compensate for the exhaust gases discharged from the processing parts 10a and 10b in the collecting exhaust pipe 22i.

Since the individual guide area of the guide pipe 25Ab is set larger than that of the guide pipe 25Ac, the flow rate of outside gas flowing into the collecting exhaust pipe 22i in FIG. 14 is higher that of outside gas flowing into the collecting exhaust pipe 22i in FIG. 13.

As described above, even when the number of the processing parts 10 connected in communication with the collecting exhaust pipe 22i is consistent, the guide area A is smaller as the positions at which the processing parts 10 connected in communication with the collecting exhaust pipe 22i are disposed are higher. This enables outside gas to flow into the collecting exhaust pipe 22i at an appropriate flow rate corresponding to the fluidity of the exhaust gas flowing through the collecting exhaust pipe 22i. Thus, the pressure variations in the collecting exhaust pipe 22i can be reduced with higher accuracy. Furthermore, setting the individual guide areas of the guide pipes 25 to values equivalent to the flow rate of the exhaust gas from the corresponding processing part 10 can make flow rates of the gases flowing into the collecting exhaust pipe 22i almost constant, irrespective of a switching state of the switcher 23. Thus, the pressure variations in the collecting exhaust pipe 22i can be reduced with much higher accuracy. The same applies to the collecting exhaust pipes 22j and 22k.

In Embodiment 2, the controller 90 need not calculate the guide area of the outside gas introducer 24. Thus, the computation load of the controller 90 can be reduced.

In the examples above, the horizontal exhaust pipe 222 of the collecting exhaust pipe 22i is common to two of the towers 40 (e.g., the towers 40A and 40B). However, the horizontal exhaust pipe 222 is not always limited to this. For example, the collecting exhaust pipe 22i may be disposed for each of the towers 40 as described in Embodiment 1.

Although the substrate processing apparatus 100 is described in detail, the description is in all aspects illustrative and does not restrict the substrate processing apparatus 100. Therefore, numerous modifications and variations that have not yet been exemplified are devised without departing from the scope of the present disclosure. The structures described in Embodiments and the modifications can be appropriately combined or omitted unless any contradiction occurs.

While the disclosure has been shown and described in detail, the foregoing description is in all aspects illustrative and not restrictive. It is therefore understood that numerous modifications and variations can be devised without departing from the scope of the disclosure.

What is claimed is:

1. A substrate processing apparatus, comprising:
a first tower including a plurality of first processing parts which are aligned in a vertical direction and each of which processes a substrate;
a plurality of first individual exhaust pipes through which respective gases discharged from the plurality of first processing parts flow;
a first collecting exhaust pipe;
a first switcher switching between connection and disconnection between each of the first individual exhaust pipes and the first collecting exhaust pipe;
a first outside gas introducer including a flow passage introducing outside gas from outside to the first collecting exhaust pipe, the flow passage having a variable guide area; and
a controller controlling the guide area of the first outside gas introducer, based on individual guide areas corresponding to the plurality of first processing parts and switching states of the first switcher, the individual guide areas corresponding to the plurality of first processing parts being set according to positions at which the plurality of first processing parts are disposed.

2. The substrate processing apparatus according to claim 1,
wherein the controller controls the guide area, based on a sum of the individual guide area(s) corresponding to first processing part(s) disconnected from the first collecting exhaust pipe from among the plurality of first processing parts, and
the individual guide areas are set to larger values as the positions at which the plurality of first processing parts are disposed are higher.

3. The substrate processing apparatus according to claim 1,
wherein the first outside gas introducer includes:
a single guide pipe disposed in the first collecting exhaust pipe; and
a movable part adjusting the guide area of the single guide pipe and controlled by the controller.

4. The substrate processing apparatus according to claim 3, further comprising
a storage in which individual area data indicating the individual guide areas corresponding the plurality of first processing parts is prestored,
wherein the controller controls the movable part, based on the switching states and the individual area data.

5. The substrate processing apparatus according to claim 1,
wherein the first outside gas introducer includes:
a plurality of guide pipes having the individual guide areas corresponding the plurality of first processing parts; and
a plurality of on-off valves switching between opening and closing the plurality of guide pipes,
wherein the controller controls the plurality of on-off valves based on the switching states.

6. The substrate processing apparatus according to claim 1, comprising:
a second tower including a plurality of second processing parts which are aligned in the vertical direction and each of which processes a substrate, the second tower and the first tower being aligned in a horizontal direction;
a plurality of second individual exhaust pipes through which respective gases discharged from the plurality of second processing parts flow;
a second collecting exhaust pipe;
a second switcher switching between connection and disconnection between each of the second individual exhaust pipes and the second collecting exhaust pipe; and
a second outside gas introducer including a flow passage introducing outside gas from outside to the second collecting exhaust pipe, the flow passage having a variable guide area,
wherein the controller controls the guide area of the second outside gas introducer, based on individual guide areas corresponding to the plurality of second processing parts and switching states of the second switcher, and the individual guide areas corresponding to the plurality of second processing parts being different from one another.
